(19) United States
(12) Patent Application Publication
(10) Pub. No.: US 2023/0019869 A1
(43) Pub. Date: Jan. 19, 2023

(54) OPTICALLY OCCLUSIVE PROTECTIVE ELEMENT FOR BONDED STRUCTURES

(71) Applicant: Invensas Bonding Technologies, Inc., San Jose, CA (US)

(72) Inventors: Laura Wills Mirkarimi, Sunol, CA (US); Rajesh Katkar, Milpitas, CA (US)

(21) Appl. No.: 17/812,675

(22) Filed: Jul. 14, 2022

Related U.S. Application Data
(60) Provisional application No. 63/203,332, filed on Jul. 16, 2021.

(51) Int. Cl. H01L 23/00; H01L 23/498

(52) U.S. Cl. CPC H01L 23/573; H01L 23/49827

(57) ABSTRACT

An optically occlusive protective element for bonded structures, embodiments of which disclosed herein relate to directly bonded structures along a bond interface. Specifically, two elements, a semiconductor element and an occlusive element, may be directly bonded to one another without an intervening adhesive along a bonding interface. The semiconductor element includes active circuitry which, after bonding, is protected by the occlusive element. The occlusive element includes several optically occlusive layers which are arranged to inhibit an optical interrogation of the active circuitry. Such layers may further include occlusive strips which may or may not overlap with other occlusive strips from other occlusive layers when the occlusive layers are stacked vertically.

### BACKGROUND

### Field

The field relates to optically obstructive protective elements for bonded structures and methods for forming the same.

### Description of the Related Art

Semiconductor chips (e.g., integrated device dies) may include active circuitry containing security-sensitive components which contain valuable and/or proprietary information, structures or devices. For example, such security-sensitive components may include an entity's intellectual property, software or hardware security (e.g., encryption) features, privacy data, or any other components or data that the entity may wish to remain secure and hidden from third parties. For example, third party bad actors may utilize various techniques to attempt to access security-sensitive components for economic and/or geopolitical advantage. Accordingly, there remains a continuing need for improving the security of semiconductor chips from being accessed by third parties.

### SUMMARY

A bonded structure is disclosed herein which includes a semiconductor element including active circuitry; and an obstructive element directly bonded to the semiconductor element without an adhesive along a bonding interface, the obstructive element including at least one patterned optically obstructive layer disposed over the active circuitry and inhibiting optical reading of the active circuitry. In some embodiments, the at least one patterned optically obstructive layer includes a plurality of optically occlusive layers. In some embodiments, the plurality of optically occlusive layers is disposed over and spaced apart from one another along a direction transverse to the bonding interface. In some embodiments, each optically occlusive layer of the plurality of optically occlusive layers includes a nonconductive layer and a patterned opaque material at least partially embedded in the nonconductive layer. In some embodiments, the patterned opaque material includes a plurality of occlusive strips extending along a direction generally parallel with the bonding interface. In some embodiments, the plurality of occlusive strips includes one or more conductive materials. In some embodiments, the one or more conductive materials comprises copper. In some embodiments, the patterned opaque material includes a material that blocks light at wavelengths in a range of 400 nm to 1 mm. In some embodiments, the patterned opaque material includes a material that blocks light at wavelengths in a range of 800 nm to 2500 nm. In some embodiments, the patterned opaque material is opaque to at least one of infrared (IR) or near infrared (NIR) light.

In some embodiments, a first optically occlusive layer of the plurality of optically occlusive layers includes a first opaque pattern and a second optically occlusive layer of the plurality of optically occlusive layers includes a second opaque pattern at least partially non-overlapping with the first opaque pattern such that, in a top view of the occlusive element, the first and second opaque patterns occlude a larger portion of the semiconductor element than the first and second opaque patterns alone. In some embodiments, the first opaque pattern includes a first plurality of occlusive strips and the second opaque pattern includes a second plurality of occlusive strips at least partially non-overlapping with the first plurality of occlusive strips. In some embodiments, the occlusive element further includes at least three optically occlusive layers, and wherein the patterned occlusive material occludes a predefined area of the semiconductor element in a plane parallel to the optically occlusive layers. In some embodiments, the optically occlusive layers are configured to provide at least 75% occlusion over the predefined area. In some embodiments, the optically occlusive layers are configured to provide at least 95% occlusion over the predefined area. In some embodiments, the predefined area includes at least 75% of a bonding surface of the first semiconductor element. In some embodiments, the predefined area includes at least 95% of a bonding surface of the first semiconductor element.

In some embodiments, the semiconductor element includes at least one sensitive circuit region and at least one region devoid of sensitive circuitry, the patterned opaque material occluding at least a portion of the at least one sensitive circuit region and leaving the at least one region devoid of sensitive circuitry unoccluded. In some embodiments, the plurality of optically occlusive layers includes one or more optical filtering layers. In some embodiments, the at least one patterned optically obstructive layer includes a material that refracts, scatters, diffuses, diffracts, or phase shifts light to inhibit optical reading of the active circuitry. In some embodiments, the semiconductor element further includes a bonding layer, and wherein the obstructive element further includes a bonding layer directly bonded to the bonding layer of the semiconductor element. In some embodiments, the bonding layer of the obstructive element is metallized to match a metallization pattern of the semiconductor element. In some embodiments, the bonding layer of the semiconductor element includes a plurality of contact pads disposed in a nonconductive layer, and wherein the bonding layer of the obstructive element comprises a plurality of contact pads disposed in a nonconductive layer directly bonded to the contact pads of the semiconductor element. In some embodiments, the bonding layer of the obstructive element and an optically occlusive layer spaced vertically from the bonding layer along a direction transverse to the bonding interface are connected through at least one vertical interconnect. In some embodiments, at least two of a plurality of occlusive layers which are next to one another have no vertical interconnects between them. In some embodiments, the active circuitry is disposed at or near an active side of the semiconductor element, the obstructive element directly bonded to a back side of the semiconductor element that is opposite the active side. In some embodiments, a first occlusive layer of the plurality of optically occlusive layers includes a detection circuit configured to detect external access of the first occlusive layer. In some embodiments, the detection circuit includes a passive electronic circuit element configured to detect the external access. In some embodiments, the passive electronic circuit includes a capacitive circuit element or a resistive circuit element. In some embodiments, the bonded structure further includes a vertical interconnect extending from the detection circuit to a contact pad of the obstructive element. In some embodiments, the obstructive element is directly bonded to a back side of the semiconductor element opposite an active side, the bonded structure further including a through semiconductor via (TSV) extending from a contact pad at or near the active side of the semiconductor element to the contact pad of the obstructive element, the TSV providing electrical communication between the semiconductor element and the detection circuit. In some embodiments, the contact pad of the obstructive element is directly bonded to a contact pad at an active side of the semiconductor element. In some embodiments, an obstructive layer of the at least one optically obstructive layer further includes an optical filter.

A bonded structure is disclosed herein which includes a semiconductor element including active circuitry; and an obstructive element directly bonded to the semiconductor element without an adhesive along a bonding interface, the obstructive element including a first obstructive layer and a second obstructive layer disposed over the first obstructive layer, the first obstructive layer having a first obstructive pattern and the second obstructive layer having a second obstructive pattern at least partially non-overlapping with the first obstructive pattern. In some embodiments, in a top view of the obstructive element, the first and second obstructive patterns cooperate to inhibit optical reading of the active circuitry. In some embodiments, the obstructive patterns include one or more conductive materials. In some embodiments, the one or more conductive materials includes copper. In some embodiments, the patterned obstructive material includes a material that blocks light at wavelengths in a range of 700 nm to 1 mm. In some embodiments, the patterned obstructive material includes a material that blocks light at wavelengths in a range of 800 nm to 2500 nm. In some embodiments, the patterned obstructive material is opaque to at least one of infrared (IR) or near infrared (NIR) light. In some embodiments, the semiconductor element further includes a bonding layer, and wherein the obstructive element further includes a bonding layer directly bonded to the bonding layer of the semiconductor element. In some embodiments, the bonding layer of the semiconductor element includes a plurality of contact pads disposed in a nonconductive layer, and wherein the bonding layer of the obstructive element includes a plurality of contact pads disposed in a nonconductive layer directly bonded to the contact pads of the semiconductor element. In some embodiments, the first obstructive layer further includes a detection circuit configured to detect external access of the first obstructive layer. In some embodiments, the bonded structure includes a vertical interconnect extending from the detection circuit to a contact pad of the obstructive element. In some embodiments, the obstructive element is directly bonded to a back side of the semiconductor element opposite an active side, the bonded structure further including a through semiconductor via (TSV) extending from a contact pad at or near the active side of the semiconductor element to the contact pad of the obstructive element, the TSV providing electrical communication between the semiconductor element and the detection circuit.

A method of forming a bonded structure is disclosed herein, the method including directly bonding a semiconductor element to an obstructive element without an adhesive, the semiconductor element including active circuitry, and the obstructive element including at least one patterned optically obstructive layer disposed over the active circuitry and that inhibits optical reading of the active circuitry. In some embodiments, the method includes forming the obstructive element such that a plurality of optically obstructive layers are spaced apart from one another along a direction transverse to the bonding interface. In some embodiments, the method includes forming the obstructive element such that each obstructive layer of the plurality of optically obstructive layers includes a nonconductive layer and a patterned opaque material at least partially embedded in the nonconductive layer. In some embodiments, the method includes forming the obstructive element such that the patterned opaque material includes a plurality of occlusive strips extending along a direction generally parallel with the bonding interface. In some embodiments, the method includes forming the obstructive element such that the plurality of occlusive strips includes one or more metals. In some embodiments, the method further includes forming the obstructive element such that the patterned opaque material includes a material that blocks light at wavelengths in a range of 700 nm to 1 mm. In some embodiments, the method includes forming the obstructive element such that the patterned opaque material includes a material that blocks light at wavelengths in a range of 800 nm to 2500 nm.

In some embodiments, the method includes forming the obstructive element to include a bonding layer; forming the semiconductor element to include a bonding layer; and bonding the bonding layer of the obstructive element to the bonding layer of the semiconductor element. In some embodiments, the method includes forming the obstructive element such that the bonding layer of the obstructive element is metallized to match a metallization pattern of the semiconductor element. In some embodiments, the method includes forming the obstructive element such that the bonding layer of the obstructive element includes a plurality of contact pads disposed in a nonconductive layer, the contact pads configured to mirror a plurality of contact pads of the bonding layer of the semiconductor element. In some embodiments, the method includes forming the obstructive element such that a first obstructive layer of the plurality of optically obstructive layers includes a detection circuit configured to detect external access of the first obstructive layer. In some embodiments, the method includes forming the obstructive element to include a vertical interconnect extending from the detection circuit to a contact pad of the obstructive element. In some embodiments, the method includes directly bonding the obstructive element to a back side of the semiconductor element that is directly opposite an active side of the semiconductor element, wherein the active circuitry of the semiconductor element is disposed at or near the active side of the semiconductor element and further includes a through semiconductor via (TSV) extending from a contact pad at or near the active side of the semiconductor element to the contact pad of the obstructive element, the TSV providing electrical communication between the semiconductor element and the detection circuit.

A bonded structure is disclosed herein which includes a semiconductor element including active circuitry; and an obstructive element directly bonded to the semiconductor element over the active circuitry without an adhesive along a bonding interface, the obstructive element including a plurality of conductive layers, the plurality of conductive layers including a detection circuit that monitors a passive electrical property of the obstructive element, the detection circuit in electrical communication with the active circuitry. In some embodiments, the active circuitry is configured to detect a change in the passive electrical property of the obstructive element. In some embodiments, upon detection of the change in the passive electrical property, the active circuitry is configured to transmit an alert message to an external system or user. In some embodiments, the passive electrical property includes a capacitance of the obstructive element. In some embodiments, the plurality of conductive layers includes a first conductive layer, a second conductive layer, and a dielectric layer between the first and second conductive layers. In some embodiments, the obstructive element is directly bonded to a back side of the semiconductor element that is opposite a front side of the semiconductor element, the active circuitry disposed closer to the front side than the back side. In some embodiments, the bonded structure includes a through substrate via (TSV) to provide electrical communication between the active circuitry and the detection circuit. In some embodiments, the plurality of conductive layers serves as an optically-obstructive structure that inhibits optical reading of the active circuitry. In some embodiments, the plurality of conductive layers including a first obstructive pattern and a second obstructive pattern at least partially non-overlapping with the first obstructive pattern.

A bonded structure is disclosed herein which includes a semiconductor element having a front side and a back side opposite the front side, the semiconductor element including active circuitry disposed closer to the front side than the back side; and an obstructive element directly bonded to the back side of the semiconductor element over the active circuitry without an adhesive along a bonding interface, the obstructive element including a detection circuit that monitors a passive electrical property of the obstructive element, the detection circuit in electrical communication with the active circuitry.

### BRIEF DESCRIPTION OF THE DRAWINGS

FIG. 1 is an example illustration of near-infrared (NIR) imaging of a semiconductor chip.

FIG. 2A is a schematic side sectional view of a protective element having multiple occlusive layers.

FIG. 2B is a schematic side sectional view of a protective element having multiple occlusive layers.

FIG. 3 is a schematic top sectional view of a protective element illustrating superimposition of occlusive layers.

FIG. 4A is a schematic side sectional view of a protective chip bonded to the active side of an active chip.

FIG. 4B is a schematic side sectional view of a protective chip bonded to the passive side of an active chip.

FIG. 5A is a schematic side sectional view of a protective chip incorporating an optical filter layer bonded to the active side of an active chip.

FIG. 5B is a schematic side sectional view of a protective chip combining an optical filter layer and embedded random reflective patterns bonded to the active side of an active chip.

### DETAILED DESCRIPTION

As explained herein, third parties (such as third party bad actors) may attempt to access security-sensitive components on elements such as integrated device dies. In some elements, the security-sensitive components may be protected by a combination of netlist and non-volatile memory (NVM) data. However, third parties may attempt to hack the security-sensitive components by a combination of destructive and non-destructive techniques, e.g., probing and/or delayering the element to expose or otherwise gain access to the security-sensitive components. In some cases, the third party may attempt to hack the security-sensitive components by pulsing electromagnetic (EM) waves onto active circuitry of the element, using fault injection techniques, employing near infrared (NIR) laser triggering or focused ion beam (FIB) modification of circuits, chemical etching techniques, and other physical, chemical, and/or electromagnetic hacking tools and even reverse engineering. These techniques can be used to physically access sensitive circuits of microdevices such as integrated circuits to directly read encrypted information, to trigger circuits externally to release information otherwise encrypted, to understand manufacturing processes, or even to extract enough information to be able to eventually replicate sensitive designs. For example, in some cases hackers may attempt to access the encryption key, which can be stored in the circuit design, in memory, or in a combination of both. Techniques can also be used to indirectly read sensitive information by analyzing the resultant output based upon fault injection inputs, and through recursive analysis determine the encryption key or data contents. It is challenging to structurally protect the security-sensitive components on elements such as integrated device dies or chips.

Accordingly, it is important to provide improved security for elements (such as semiconductor integrated device dies) that include security-sensitive components. Various embodiments disclosed herein relate to a bonded structure including a first semiconductor element bonded to a second semiconductor element. The second semiconductor element can comprise a protective or obstructive element including at least one (e.g., a plurality of) patterned obstructive layers disposed over active circuitry of the first semiconductor element and arranged to inhibit an optical interrogation or optical access of the active circuitry.

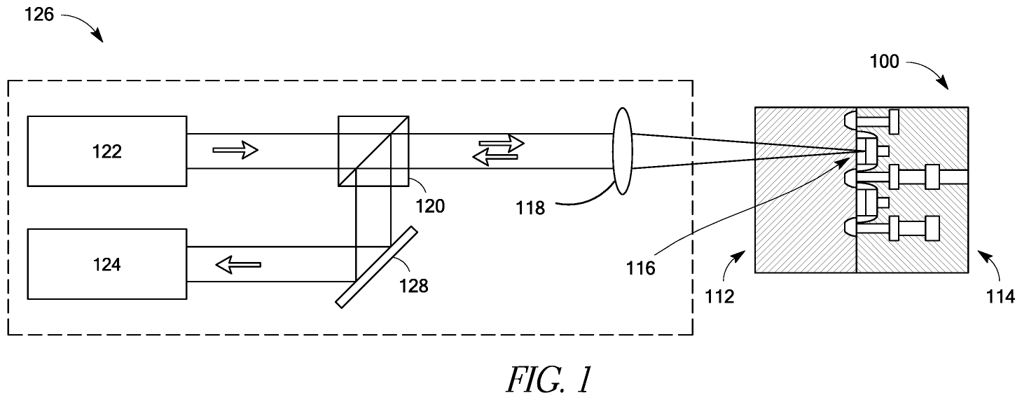

FIG. 1 illustrates a conventional approach to imaging a semiconductor element 100 using a near-infrared (NIR) optical probe 126, for example, to probe sensitive circuitry of the semiconductor element 100. As shown in FIG. 1, optical probing techniques may be used to access active circuitry 116 of a semiconductor element 100. Optical probing techniques can enable an attacker to reconstruct sensitive circuitry, compromising the confidentiality and security of the sensitive circuitry. Optical probing techniques may be used to access active circuitry 116 from a back side 112 of the semiconductor element 100 as the optical probes 126 from backside are not blocked by any wiring or metallizations, unlike on the frontside 114 of the semiconductor element 100. The optical probe 126 includes a laser source 122, a beam splitter 120, a detector 124, and an objective lens 118. The laser source 122 can create and direct a laser beam to the beam splitter 120, which can split the beam into a first component that is directed through the objective lens 118 to the semiconductor element 100 and a second component that is directed to a mirror 128 and the detector 124. The back side optical intrusion techniques can also be used to monitor activity of a circuit, collecting bitstream information to retrieve encryption keys and compromise encrypted information.

Preventing optical intrusion is thus important to ensuring the security of semiconductor elements containing security-sensitive components. Conventional techniques may include packaging semiconductor elements 100 with occlusive casings. However, conventional packaging may be susceptible to grinding, chemical etching, and other removal processes that are relatively unsophisticated, leaving the sensitive circuitry exposed and susceptible to optical probing. It may thus be desirable to include protection against optical intrusions by bonding protective or occlusive elements directly to the semiconductor element 100. Semiconductor elements 100, such as integrated device dies or chips, may be mounted or stacked on other elements. For example, a semiconductor element 100 can be mounted to a carrier, such as a package substrate, an interposer, a reconstituted wafer or element, etc. As another example, a semiconductor element 100 can be stacked on top of another semiconductor element 100, e.g., a first integrated device die can be stacked on a second integrated device die. In some arrangements, a through-substrate via (TSV) can extend vertically through a thickness of the semiconductor element 100 to transfer electrical signals through the semiconductor element 100, e.g., from a first surface of the semiconductor element 100 to a second opposing surface of the semiconductor element 100. Embodiments of the present disclosure are directed at bonded structures including protective chips comprising obstructive layers bonded directly to active chips that may comprise security-sensitive circuitry or circuit elements.

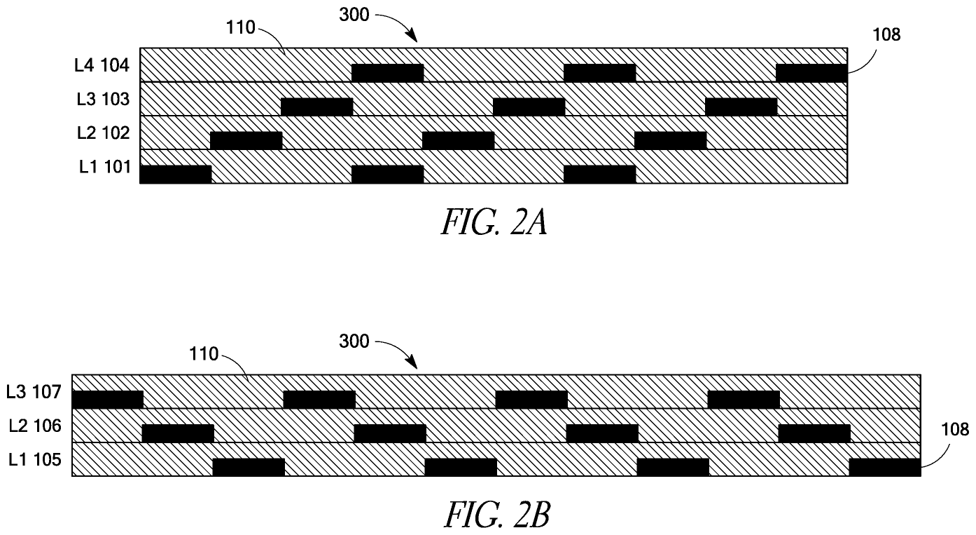

FIGS. 2A-2B illustrate side sectional views of protective chips 300 (also referred to herein as obstructive chips) comprising at least one obstructive layer. In the embodiment of FIGS. 2A-2B, the at least one obstructive layer comprises a plurality of stacked occlusive (e.g., light-blocking) layers (layers L1-L4 101-104 shown in FIG. 2A, and layers L1-L3 105-107 shown in FIG. 2B), according to various embodiments. Conventional techniques for optical occlusion outside of the semiconductor industry may typically comprise a solid sheet or layer of metal or other occlusive material surrounding a sensitive circuit. However, a single occlusive layer may be unsuitable for incorporating into semiconductor elements due, inter alia, to the differing thermo-mechanical properties of the occlusive materials and the semiconductor materials. For example, if a single blanket layer of metal (such as copper) were included in the semiconductor element, the large continuous sheet of metal may induce thermo-mechanical stresses when processed at elevated temperatures. In various processes, therefore, the maximum metal coverage of a typical complementary metal-oxide semiconductor (CMOS) within a particular layer may be in a range of 15% to 45%, in a range of 20% to 40%, in a range of 22% to 35%, or in a range of 25% to 33% of a total area of the layer in order to prevent destructive thermo-mechanical stresses between the materials.

To reduce the thermo-mechanical stress while providing greater obstruction, multiple layers may be disposed into an occlusive structure of a protective or obstructive element (e.g. protective chip 300). FIG. 2A shows a cross-section of an example semiconductor element 300 formed from four layers of a semiconductor element with partial metallization of each layer. The layers shown can comprise a plurality of (e.g., four) patterned back-end-of-line layers, e.g. occlusive layers L1-L4 (101, 102, 103, and 104), with each layer L1-L4 including a nonconductive material 110 (such as a dielectric material, like silicon oxide or silicon nitride) and a pattern of occlusive (e.g., metallic, opaque) strips 108 or other shapes formed in the layer. The strips 108 can comprise a conductive material such as copper or any other suitable metal in various embodiments which blocks incoming incident light beams.

Accordingly, the occlusive material (e.g. opaque strips 108) may comprise a material that blocks the transmission of light (or most of the light) from passing through the obstructive chip 300. In embodiments that utilize occlusive strips, the occlusive material can comprise a material that is opaque to (e.g., absorbs or reflects) light at wavelengths of the incident beam. For example, in the illustrated embodiment of FIG. 2A, the occlusive strips 108 comprise an opaque material, such as a metal (e.g., copper in some embodiments). In other embodiments, the occlusive material can comprise other types of material that block or substantially block the transmission of light at the wavelength(s) of the incident beam(s). For example, in other embodiments, a patterned occlusive material can comprise one or multiple filtering layers that transmit at least some light at one or more first wavelengths and that blocks at least some light at one or more second wavelengths (e.g., by way of absorption and/or interference). Thus, various obstructive optical materials can block (or substantially block) light using opaque materials or materials that filter light at various wavelengths. Additionally or alternatively, in some embodiments, the obstructive optical material can comprise an optical material that obstructs light in other ways. For example, in such embodiments, the obstructive material can change the direction of an incoming or outgoing beam (e.g. refract), focus or de-focus (e.g. lensing) the beam, scatter the beam, diffuse the beam, diffract the beam (e.g., a grating), phase/wavelength shift the beam, etc. Thus, the optical obstructive materials described herein refer to light-blocking or light-modifying materials that block or modify incident light utilized when attempting to hack sensitive circuitry. Some of the obstructive materials may include material that has undergone roughening in order to achieve the above desired effect. As explained herein in the context of the opaque occlusive strips 108, the obstructive material layers may be patterned so as to create at least one optical obstructive layer (e.g., a plurality of obstructive layers) that inhibits optical reading of active circuitry.

In the example of FIG. 2A, the occlusive strips 108 can be arranged generally parallel to a bonding surface of the protective element 300 and can extend parallel to one another. In some embodiments, the strips 108 can extend across a majority of a width of the chip 300, e.g., substantially entirely across the width of the chip 300, as seen from a top plan view. As used herein, the patterned opaque material comprises one or more occlusive strips 108 of a single occlusive layer (e.g. one of 101-104). In some embodiments, as explained herein, the patterned opaque material of the occlusive layer includes an occlusive strip 108 that is made of a material that occludes (e.g., which blocks) at least 90% of light in a range of 400 nm to 1 mm, at least 90% of light in a range of 800 to 2500 nm, e.g., at least 90% of near infrared (NIR) light. In various embodiments, the patterned opaque material of the occlusive layers 101-104 can block at least 95% or at least 99% of light in a range of 400 nm to 1 mm, at least 90% of light in a range of 800 to 2500 nm, e.g., at least 90% of near infrared (NIR) light. Additionally or alternatively, the patterned opaque material can block at least 90%, at least 95%, or at least 99% of infrared (IR) light or ultraviolet (UV) light. In such embodiments that utilize an optical obstructive material that comprises an occlusive layer, the material can comprise an opaque layer (e.g., metallic strips 108), one or more filtering layers, or any other light-blocking layer.

As explained above, in other embodiments, the optical obstructive material can comprise other types of light-modifying materials, such as materials that refract, reflects, scatters, diffuses, diffracts, phase shifts etc., at least 90%, at least 95%, or at least 99% of light having a wavelength in a range of 400 nm to 1 mm, 800 nm to 2500 nm, near-infrared (NIR) light, infrared light (IR) or UV light. In embodiments that utilize non-occlusive obstructive materials, at least some of the incoming light may pass through the obstructive element 300, impinge on the active circuitry 116, and reflect back through the obstructive element 300. However, the non-occlusive obstructive material may interact with the reflected light so as to modify the amplitude and/or phase of the light, which can inhibit optical reading of the active circuitry by an optical probe.

In the illustrated occlusive example of FIG. 2A, the occlusive pattern of the strips 108 in layers 101-104 (or layers 102-104) can cooperate to form an optical obstructive structure to substantially or entirely block a light beam that is used to probe active circuitry within the underlying active chip 310. In some embodiments, for example, the occlusive pattern can block 90% to 100%, or 95% to 100% of light incident on the occlusive (e.g. opaque) strips 108. For example, the strips 108 can be selected to be opaque to light used in optical probes, such as NIR light. When provided in the at least partially non-overlapping manner described herein, the occlusive layers can substantially block light from a probing technique. Thus, the plurality of occlusive or opaque strips 108 can be arranged such that, when viewed from a top plan view, the strips cooperate to form an optically obstructive structure that inhibits (e.g., substantially prevents) light from impinging on sensitive circuitry and, accordingly, inhibits optical reading of the active circuitry. Thus, each of the individual occlusive layers (e.g. one of 101-104) is only partially obstructive. For instance, occlusive layer 101, by itself, may only block 20%-40% of incident light. However, these layers are combined (e.g. FIG. 2A-B) to form a substantially fully occlusive element which blocks or inhibits most, or all, incident light and which is opaque to optical insertion. As shown in FIG. 2A, complete obstruction (e.g., occlusion) or substantially complete obstruction (e.g., occlusion) may be achieved with a maximum per-layer metal coverage of approximately 25% of a total area of each layer. In such an arrangement, therefore, four (4) layers may be provided on top of one another, with the optically occlusive (e.g. opaque) strips 108 staggered such that, from a top view, the opaque strips 108 completely or substantially completely cover at least sensitive circuitry of an underlying active chip. In some embodiments, as seen from a top view, the opaque strips 108 can cooperate to completely or substantially completely cover the entire active surface of the underlying chip, or the entire upper surface of the underlying chip or die. In other embodiments, as seen from a top view, the opaque strips 108 can cooperate to completely or substantially completely cover sensitive portions of the active circuitry of the underlying chip.

Fewer layers may be used to achieve the same level of occlusion with a greater degree of metal coverage. Unless otherwise noted, the components of FIG. 2B may be the same as or generally similar to like-numbered components of FIG. 2A. For example, FIG. 2B illustrates a cross-section of an example semiconductor element 300 formed from three layers in which the metallization of each layer may cover up to 33% percent of the layer surface. The layers shown can comprise a plurality of (e.g., 3) patterned back-end-of-line layers, L1-L3 (105, 106, and 107), with each layer L1-L3 including a nonconductive material 110 (such as a dielectric material, like silicon oxide or silicon nitride) and a pattern of occlusive (e.g., metallic, opaque) strips 108 or other shapes formed in the layer that cooperate to form a patterned optical obstructive material. As discussed in greater detail below, patterning of the metallization may also be employed to achieve occlusion of sensitive areas while limiting the total metallization of the occlusive elements 101-104. In some embodiments, the occlusive material of the strips 108 may be a metal, such as copper. In other embodiments, different occlusive or obstructive materials may be used. In some embodiments, as explained above, these materials may be selected to occlude (e.g, be opaque or reflective) or to otherwise obstruct (e.g., selected to refract, scatter, diffuse, phase shift etc., at least 90%, at least 95%, or at least 99%) light with wavelengths in the range of 400 nm to 1 mm, for example. In various embodiments, the materials may be selected to obstruct (e.g., which blocks, refracts, reflects, scatters, diffuses, phase shifts etc., at least 90%, at least 95%, or at least 99%) light with wavelengths in the range of 800 nm to 2500 nm. In various embodiments, the materials may be selected to obstruct near-infrared (NIR) light, infrared light, or UV light.

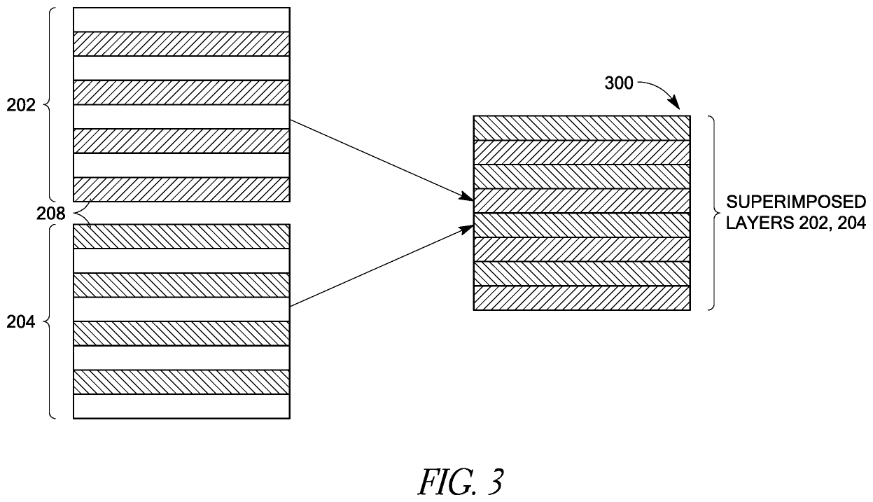

FIG. 3 depicts an overhead view of an illustrative embodiment of an optically obstructive semiconductor element 300 comprising layers 202 and 204. As shown in FIG. 3, each layer 202, 204 surface may be partially metallized with obstructive layers comprising occlusive strips 208 to provide an optically occlusive barrier. Each layer may further be metallized according to a different pattern. Illustratively, the at least partially non-overlapping metallization patterns in the separate layers 202, 204 may be configured so that, when stacked and seen from a top view, the layers cooperate to form an overlapping (or substantially overlapping) occlusive barrier as seen from above. For example, element 300 shows an overhead view of layers 202 and 204 with their metallization patterns 208 superimposed. In this way, multiple partially metallized layers may be formed in a single protective semiconductor element 300 providing greater occlusion than can be achieved with a single layer. It should be understood by one skilled in the art that the protective chip 300 shown in FIG. 3 is illustrative only, and that other embodiments may have more than two (2) layers. Additionally, other embodiments may employ different metallization patterns 208 to achieve occlusion. For example, other complementary patterns for the layers 202, 204 can be used, provided that, when seen from a top view, the complementary pattern of layers 202, 204 substantially occludes at least sensitive portion of the underlying active circuitry. In still other embodiments, for example embodiments that utilize a non-occlusive obstructive material, the obstructive material can be patterned in one layer. For example, in embodiments that scatter, diffract, or diffuse light, the obstructive layer can be patterned such that at least some light may pass through the obstructive element 300, reflect or scatter from the active chip 310, and be absorbed or canceled by way of interference from the patterned obstructive layer(s). Additional example of optical obstruction materials may be found throughout (including at least in ¶¶ [0030], [0036], [0051], and [0066]-[0067] of) U.S. patent application Ser. No. 16/844,932, published as U.S. Patent Publication No. US 2020/0328162, the entire contents of which are incorporated by reference herein in their entirety and for all purposes.

Further, in some embodiments the one or more obstructive layers (e.g., metallization pattern 208 of an occlusive structure) may be irregular, or cover only part of the area of the chip 206. For example, an active chip may have sensitive circuitry covering only a portion of the area of the chip. To improve cost and performance characteristics, the protective chip 300 may be configured to obstruct (e.g., occlude) only the sensitive portion of the active circuitry, and not to obstruct (e.g., occlude or block) other portions of the chip that do not include circuitry or that include non-sensitive circuitry. Further, in some embodiments, complete obstruction or occlusion may be unnecessary to disrupt an optical probe attack. In these embodiments, the obstructive layer(s) (e.g., occlusive layers 202, 204) of the protective chip 300 may be configured to provide partial obstruction or occlusion of sensitive areas of the bonded active chip. For example, an active chip using only partial occlusion may be bonded to a protective chip 300 comprising overlapping occlusive layers 202, 204 patterned by a lower-precision, lower-cost process. The lower precision may thus result in areas of partial occlusion sufficient to provide the desired protection over the sensitive area of the active chip at a cheaper cost per chip. For example, the occlusive layers may be configured to provide desired protection over an area of the active chip in a range of 50% to 75%, in a range of 75% to 95%, or in a range of 95% to 100% of the sensitive circuit area, or, in some embodiments, in a range of 50% to 75%, in a range of 75% to 95%, or in a range of 95% to 100% of the overall active area of the chip 310.

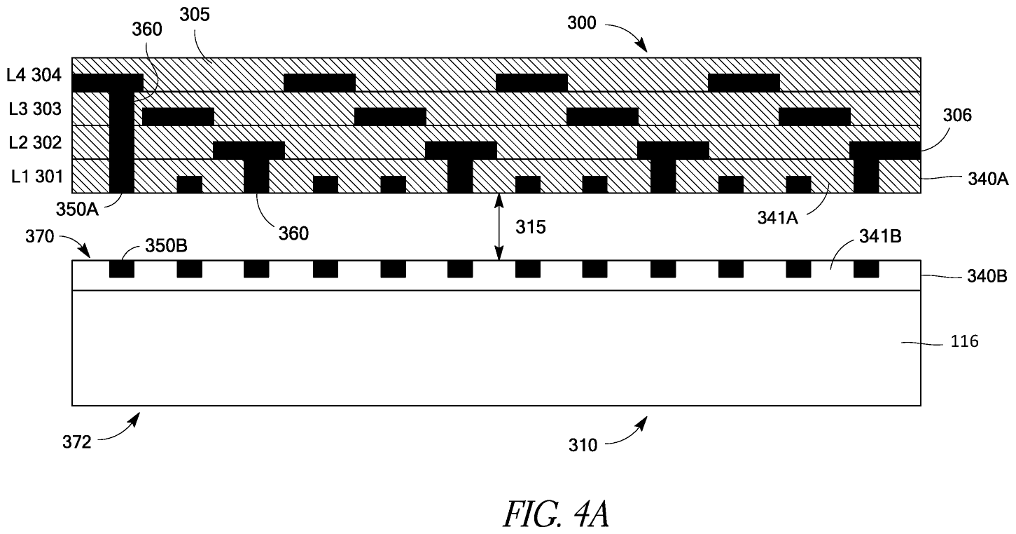

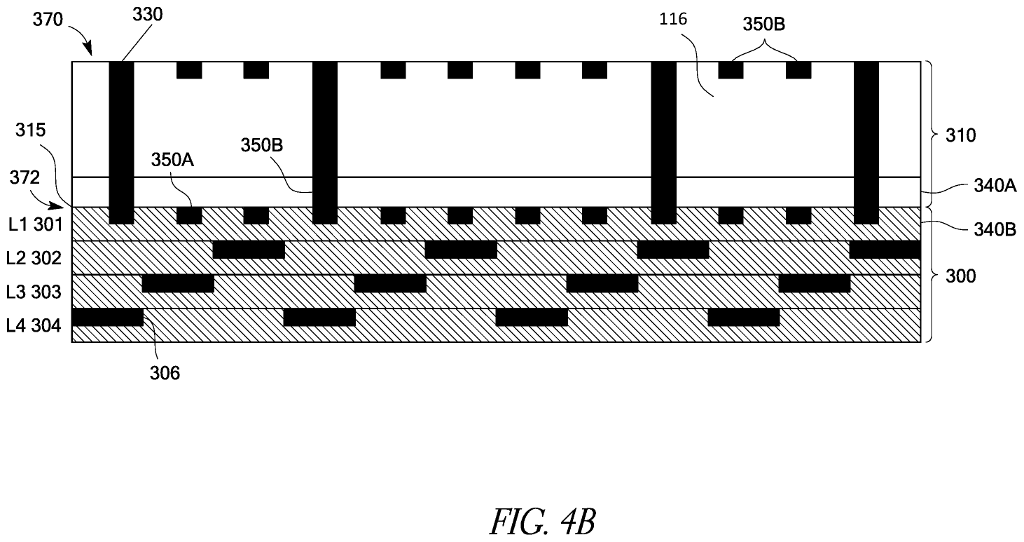

FIG. 4A depicts active-side bonding of a protective chip 300 with an active chip 310 across a bond interface 315, prior to direct bonding. Unless otherwise noted, the components and functionality of the structure of FIG. 4A may be the same as or generally similar to the components of FIGS. 2A-3. As described above, non-bonded protective structures may be susceptible to removal via various removal techniques, such as grinding or etching. It may therefore be desirable to directly bond a protective chip 300 and an active chip 315 to form a bonded structure. In some embodiments, a bond interface 315 may comprise a bond between a bonding layer 340A of the protective chip 300 and a bonding layer 340B of the active chip 310. In some embodiments, the direct bond may comprise a nonconductive non-adhesive bond in which nonconductive field regions 341A, 341B (e.g., dielectric materials) of the elements (e.g. protective chip 300 and active chip 310) are directly bonded to one another. In other embodiments, such as the embodiment shown in FIG. 4A, the direct bond may comprise a hybrid bond in which contact pads 350B of the active chip 310 are directly bonded to corresponding contact pads 350A of the protective chip 300, and in which nonconductive regions (e.g., nonconductive field regions 341B) of the active chip 310 are directly bonded to corresponding nonconductive regions (e.g., a nonconductive field region 341A) of the protective chip 300. As shown in FIG. 4A, the bonding layer 340A, 340B of each chip 300, 310 may comprise a plurality of contact pads 350A, B disposed in a nonconductive field regions 341A, 341B, such as a dielectric layer (e.g., silicon oxide, silicon nitride, silicon oxynitrocarbide, etc.). In some embodiments, the field regions 341A, 341B can comprise the same material as the nonconductive layer 305. In other embodiments, the field regions 341A, 341B can comprise a different material from the nonconductive layer 304. The contact pads 350A, B may comprise conductive material, e.g., a metal such as copper prepare for direct hybrid bonding. In these embodiments, the contact pads 350A of the protective chip 300 may be configured to mirror and/or correspond to the contact pads 350B of the active chip 310. The pads may provide an electrical and/or mechanical connection between the protective and active chips. As used herein, the pads can comprise exposed ends of through substrate vias (TSVs) 330 or vertical interconnects 360 (e.g., labeled as pad 350A) or discrete pads at least partially embedded in the field region (e.g., labeled as pad 350B).

As shown in FIG. 4A, the protective chip may comprise multiple occlusive layers 301-304, shown here as L1-L4. Each occlusive layer 301-304 may comprise a non-conductive material 305 as well as a conductive occlusive material 306. In some embodiments, the occlusive material 306 may be arranged in strips or patterns to provide partial occlusion of the active chip 310 with each layer. For example, as shown in FIG. 4A, the occlusive layers 301-304 may be patterned to provide a combined occlusive effect as explained above. As explained above, in other embodiments, other types of patterned optically-obstructive materials can be used for the layers 301-304.

As noted above, bonded structures may be subject to invasive tampering. For example, focused ion beam (FIB) techniques may be used to ablate protective layers of a chip. These techniques may thus enable an attacker to remove occlusive material from a protective chip 300 to expose the active circuitry of an active chip 310 for further optical probing. It may thus be desirable to detect ablation of the protective chip 300. In some embodiments, the contact pads 350A of the bonding layer 340A of the protective chip may be further connected by vertical interconnects 360 to one or more occlusive layers 302-304 of the protective chip 300. Likewise, the contact pads 350B of the bonding layer 340B of the active chip 310 may be connected to the active circuitry 116 of the active chip 310 through conductive traces (not shown). By bonding the contact pads 350A of the protective chip 300 to corresponding contact pads 350B of the active chip, in some embodiments the bonded structure may thus have an electrical connection between the active circuitry of the active chip 310 and one or more occlusive layers 301-304, L1-L4, of the protective chip 300. In each of the embodiments disclosed herein, the one or more occlusive layers may include bonding layer 340A, such that occlusive layer 301 may be the same as or may include at least bonding layer 340A. In some embodiments, the bonding layer 340A can be patterned to assist in occlusion (or otherwise to optically obstruct), while in other embodiments, the bonding layer 340A may not contribute substantially to occlusion, whereas layers 302-304, L2-L4 cooperate to occlude, e.g., to block impinging light from interacting with underlying sensitive circuitry.

In the illustrated embodiment, a protective chip 300 comprising four occlusive layers 301-304, L1-L4, may have vertical interconnects 360 providing electrical connections between the top-most occlusive layer 304 L4 and the contact pads 350A of the bonding layer 340A. In these embodiments, the active chip 310 may be configured to monitor one or more attributes of the protective chip 300 through the electrical connections between one or more layers of the protective chip 300 and the active chip 310. In some embodiments, the plurality of optically occlusive layers 301-304 may be disposed over and spaced apart from one another along a direction transverse to the bonding interface 315.

For example, in some embodiments the active chip 310 may be configured to measure a passive electrical property of (e.g., the capacitance of) one or more layers 301-304, a portion of a layer 301-304, or a strip 306 within a layer of the protective chip 300. In other embodiments, the active chip 310 may be configured to measure the resistance of a layer 301-304, a portion of a layer 301-304, or an element 306 within a layer 301-304 of the protective chip 300. In these embodiments, ablative hacking techniques may be detected by measuring changes in the attributes of the protective chip 300 (e.g., by measuring changes in the resistance and/or capacitance and/or impedance in the occlusive layer(s) 301-304, a portion of the occlusive layer(s) 301-304, or an element 306 within the occlusive layer(s) 301-304 to which the active circuitry is connected). For example, an FIB probe may be used to ablate a portion of an occlusive layer 301-304 of a protective chip 300 that is electrically connected to the active chip 310. As an example, the metallization within layer 304 may serve as a first terminal of a capacitive circuit, the metallization within layer 302 may serve as a second terminal of a capacitive circuit, and the intervening dielectric material 305 in layer 303 may serve as the dielectric of the capacitive circuit. The active chip 310 may detect a change in the capacitance (or resistance in other embodiments) of the protective chip 300 caused by ablation of the metallization of the occlusive layer 301-304. In these embodiments, the active chip 310 may be configured to disable operation of sensitive circuitry when ablation is detected and/or to transmit an alert message to an external system or user. In some embodiments, two or more adjacent layers of the occlusive element may have no electrical connections between them. For example, a protective chip 300 may have a first occlusive layer (e.g. layer 304) connected to one or more contact pads 350A of the bonding layer 340A with a vertical interconnect 360, and a second occlusive layer 303, that is not electrically connected to the bonding layer 350A or the first occlusive layer (e.g., which serves as an intervening dielectric of a capacitive circuit). In some embodiments, where a second occlusive layer 303 sits between the bonding layer 340A and a first occlusive layer 304, the first occlusive layer 304 may be connected to the bonding layer with the vertical interconnect 360 serving as a bypass via that skips the second occlusive layer 303 and connects to layer 304 as a terminal of a capacitive circuit. In some embodiments, the active chip 310 may measure the attributes of the protective chip 300 continuously. In other embodiments, the active chip 310 may measure attributes of the protective chip 300 periodically. In some embodiments, the active chip 310 may be configured to detect relative changes in the attributes of the protective chip 300 over time (e.g., changes in capacitance). In other embodiments, the active chip 310 may be configured to compare the attributes of the protective chip 300 to a predetermined baseline. Thus, one or more of the occlusive layers 301-304 may serve as a detection circuit configured to detect external access of the one or more occlusive layers 301-304. Additional examples of detection circuits may be found throughout U.S. Pat. No. 11,385,278, the entire contents of which are incorporated by reference herein in their entirety and for all purposes.

In the embodiment of FIG. 4A, the protective chip 300 can be bonded to an active (e.g., front) side 370 of the active chip 310, in which the contact pads 350A-B are electrically connected to active circuitry at or near the bond interface 315. In the illustrated embodiment, the protective chip 300 is shown as covering the entirety, or substantially the entirety of, the surface of the active chip 310 to which it is bonded. In such embodiments, the protective chip 300 can cover at least 10%, at least 90%, or at least 95% of an overall active area of the active chip 310. For example, the protective chip 300 can cover between 10% and 100% of the overall active area of the active chip 310, or between 90% and 99% of the overall active area of the active chip 310. As explained above, in other embodiments, the protective chip 300 can cover only a portion of the area of the active chip 310, such that the protective chip 300 covers only sensitive circuitry of the active chip 310, or only a portion of the sensitive circuitry. In some embodiments, the sensitive circuitry may be located in one or more sensitive areas of the active chip 310 and the protective chip 300 covers most or all of each of these areas. In some embodiments, the protective chip 300 may cover a portion of each of the one or more sensitive areas such that 1% to 25% of each sensitive area is covered. In some embodiments, the protective chip 300 may cover a maximum of 20% of each sensitive area. Thus, the occlusive strips 306 of the protective chip 300 need not be laterally continuous with one another. Further, the occlusive strips 306 of one layer may, but need not, overlap with the occlusive strip 306 of another layer. In some embodiments depicted herein (e.g., FIG. 2B), the occlusive pattern of each of a first and second layer may be at least partially non-overlapping.

FIG. 4B depicts a protective chip 300 directly bonded to an active chip 310 on a back side 372 of the active chip 310. The active circuitry 116 can be disposed nearer to the front side 370 than the back side 372 of the chip 310. As shown in FIG. 4B, the bond interface 315 between the protective chip 300 and the back side 372 of the active chip 310 may not contain any contact pads. In other embodiments, the bonding layers 340A, B of the protective 300 and active chip 310 may include contact pads. Further, in some embodiments, the contact pads 350A,B may provide electrical connections between the active circuitry 116 of the active chip 310 and one or more occlusive layers 301-304 of the protective chip 300 to monitor electrical characteristics of the occlusive layer 301-304 to detect intrusions such as FIB attacks, as described above. In the illustrated embodiment, for example, one or more through substrate vias (TSVs) 330 may connect contact pad(s) 350B at the front active side of the active chip 310 to corresponding contact pad(s) 350A of the protective chip 300. The vertical interconnects (see FIG. 4A) of the protective chip 300 can connect the contact pad(s) 350A of the protective chip 300 with one or more of the metallic materials 306 in one or more occlusive layers L1-L4 (301-304). Yet other embodiments may include multiple protective chips 300 direct bonded to the active chip 310 across the active side and the passive side of the active chip 310. In these embodiments, the protective chips 300 may provide protection from optical probing of both sides of the active chip 310.

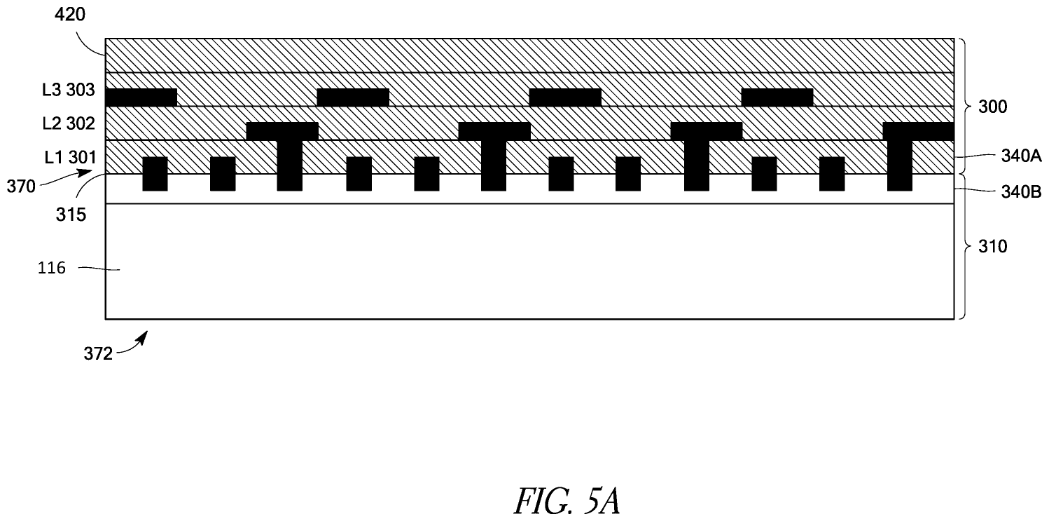

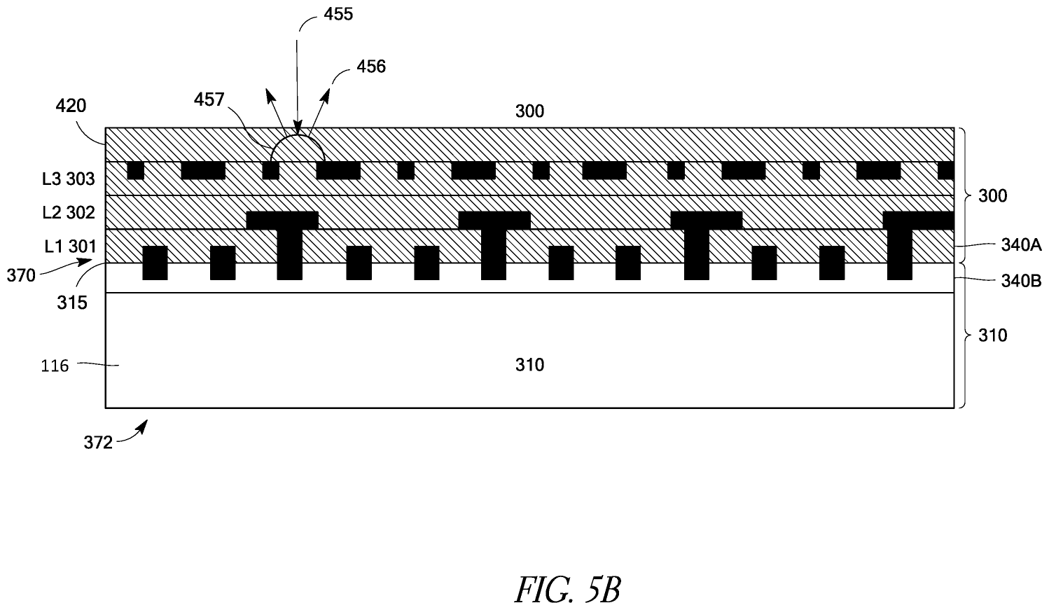

FIG. 5A shows an illustrative embodiment of a protective chip 300 directly bonded to the active side 370 of an active chip 310 across a bond interface 315, wherein the protective chip 300 further comprises an optical filter layer 420 incorporating an optical filter element. In order to increase the cost of analyzing a sensitive chip, it may be desirable to provide misleading or confusing data to an attacker in order to slow the analysis process. Instead of or in addition to blocking optical signals, it may thus be beneficial to alter the signals. In some embodiments, the optical filter element may be configured to induce a phase shift in incoming incident rays. In these embodiments, the optical filter element (which may comprise a patterned filter element) may thus generate positive or negative interference to disrupt the attacker's signal. In some embodiments, the optical filter element may comprise a metallization layer. In some embodiments, the optical filter may comprise a refractive filter. In other embodiments, the optical material may comprise other materials and structures suitable for filtering, refracting, and/or diffracting light. In some embodiments, an optical filter element may comprise more than one layer within the protective chip 300.

FIG. 5B shows an illustrative embodiment of a protective chip 300 directly bonded to the active side of an active chip 310 across a bond interface 315, wherein the protective chip 300 further comprises an optical filter layer 420 combined with an embedded random reflective pattern to form a reflective filter element 457. As shown in FIG. 5B, a reflective filter element 457 may be used to alter the optical signal from a laser probe. In these embodiments, incident rays 455 are reflected 456 away from the probe, altering the apparent intensity of the received light. This may, for example, cause an NIR probe to report inaccurate readings of the density of the probed area of the circuit.

Returning to FIG. 5A, in some embodiments the optical filter element 420 may comprise a single layer of a protective chip 300. In these embodiments, the optical filter element 420 may be bonded to a protective chip 300 further comprising one or more occlusive layers 301-303 and bonding layers 340A,B, wherein layer 301 may be a bonding layer. In other embodiments, multiple optical filter layers 420 and/or occlusive layers 301-303 may be combined in a protective chip 300. Further, a single optical filter element may comprise multiple layers. For example, a single optical filter element may comprise a single or multiple layers configured to act as a Fresnel lens. In some embodiments, an optical filter element may cover only sensitive areas of the active chip 310. In other embodiments, an optical filter element may be configured to cover the entire area of the active chip 310.

Although the illustrated embodiments herein (e.g. FIGS. 1-5) show directly bonded obstructive and active chips (e.g. 300 and 310), in other embodiments, the obstructive element 300 can be bonded to the active chip 310 with an adhesive, such as solder, a nonconductive paste, etc. Further, in some embodiments, the obstructive element 300 may be devoid of any active circuitry (e.g. devoid of transistors).

Examples of Direct Bonding Methods and Directly Bonded Structures

Various embodiments disclosed herein relate to directly bonded structures in which two elements (e.g., elements 300, 310) can be directly bonded to one another without an intervening adhesive. Two or more semiconductor elements (such as integrated device dies, wafers, etc.) may be stacked on or bonded to one another to form a bonded structure. Conductive contact pads of one element may be electrically connected to corresponding conductive contact pads of another element (e.g., contact pads 350A,B). Any suitable number of elements can be stacked in the bonded structure.

In some embodiments, the elements are directly bonded to one another without an adhesive. In various embodiments, a non-conductive or dielectric material of a first element (e.g., a protective or occlusive element) can be directly bonded to a corresponding non-conductive or dielectric field region (e.g., 341A,B) of a second element (e.g., an active chip) without an adhesive. The non-conductive material can be referred to as a nonconductive bonding region or bonding layer (e.g., 340A,B) of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface (e.g., 315) between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments and, subsequently, the bonded structure can be annealed. Upon annealing, the contact pads can expand and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 3 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die or singulated protective or occlusive element. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness.

In various embodiments, the metal-to-metal bonds between the contact pads can be joined such that copper grains grow into each other across the bond interface. In some embodiments, the copper can have grains oriented along the crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bonded structure comprising:
a semiconductor element comprising active circuitry; and
an obstructive element directly bonded to the semiconductor element without an adhesive along a bonding interface, the obstructive element comprising at least one patterned optically obstructive layer disposed over the active circuitry and inhibiting optical reading of the active circuitry.

2. The bonded structure of claim 1, wherein the at least one patterned optically obstructive layer comprises a plurality of optically occlusive layers.

3. The bonded structure of claim 2, wherein the plurality of optically occlusive layers are disposed over and spaced apart from one another along a direction transverse to the bonding interface.

4. The bonded structure of claim 2, wherein each optically occlusive layer of the plurality of optically occlusive layers comprises a nonconductive layer and a plurality of occlusive strips at least partially embedded in the nonconductive layer.

5. (canceled)

6. The bonded structure of claim 4, wherein the plurality of occlusive strips comprise one or more conductive materials.

7. (canceled)

8. The bonded structure of claim 6, wherein the patterned opaque material comprises a material that blocks light at wavelengths in a range of 400 nm to 1 mm.

9. (canceled)

10. The bonded structure of claim 6 wherein the patterned opaque material is opaque to at least one of infrared (IR) or near infrared (NIR) light.

11. (canceled)

12. The bonded structure of claim 6, wherein the first opaque pattern comprises a first plurality of occlusive strips and the second opaque pattern comprises a second plurality of occlusive strips at least partially non-overlapping with the first plurality of occlusive strips.

13. The bonded structure of claim 6, wherein the occlusive element further comprises at least three optically occlusive layers, and wherein the patterned occlusive material occludes a predefined area of the semiconductor element in a plane parallel to the optically occlusive layers.

14. The bonded structure of claim 13, wherein the optically occlusive layers are configured to provide at least 75% occlusion over the predefined area.

15. (canceled)

16. (canceled)

17. (canceled)

18. The bonded structure of claim 6, wherein the semiconductor element comprises at least one sensitive circuit region and at least one region devoid of sensitive circuitry, the patterned opaque material occluding at least a portion of the at least one sensitive circuit region and leaving the at least one region devoid of sensitive circuitry unoccluded.

19. (canceled)

20. The bonded structure of claim 1, wherein the at least one patterned optically obstructive layer comprises a material that refracts, scatters, diffuses, diffracts, or phase shifts light to inhibit optical reading of the active circuitry.

21. (canceled)

22. The bonded structure of claim 6, wherein the bonding layer of the obstructive element is metallized to match a metallization pattern of the semiconductor element.

23. (canceled)

24. The bonded structure of claim 22, wherein the bonding layer of the obstructive element and an optically occlusive layer spaced vertically from the bonding layer along a direction transverse to the bonding interface are connected through at least one vertical interconnect.

25. The bonded structure of claim 24, wherein at least two of a plurality of occlusive layers which are next to one another have no vertical interconnects between them.

26. (canceled)

27. (canceled)

28. (canceled)

29. (canceled)

30. (canceled)

31. (canceled)

32. (canceled)

33. (canceled)

34. A bonded structure comprising:
a semiconductor element comprising active circuitry; and
an obstructive element directly bonded to the semiconductor element without an adhesive along a bonding interface, the obstructive element comprising a first obstructive layer and a second obstructive layer disposed over the first obstructive layer, the first obstructive layer having a first obstructive pattern and the second obstructive layer having a second obstructive pattern at least partially non-overlapping with the first obstructive pattern.

35. The bonded structure of claim 34, wherein, in a top view of the obstructive element, the first and second obstructive patterns cooperate to inhibit optical reading of the active circuitry.

36. (canceled)

37. (canceled)

38. (canceled)

39. (canceled)

40. (canceled)

41. The bonded structure of claim 35, wherein the semiconductor element further comprises a bonding layer, and wherein the obstructive element further comprises a bonding layer directly bonded to the bonding layer of the semiconductor element.

42. The bonded structure of claim 41, wherein the bonding layer of the semiconductor element comprises a plurality of contact pads disposed in a nonconductive layer, and wherein the bonding layer of the obstructive element comprises a plurality of contact pads disposed in a nonconductive layer directly bonded to the contact pads of the semiconductor element.

43. The bonded structure of claim 35, wherein the first obstructive layer further comprises a detection circuit configured to detect external access of the first obstructive layer.

44. The bonded structure of claim 43, further comprising a vertical interconnect extending from the detection circuit to a contact pad of the obstructive element.

45. The bonded structure of claim 44, wherein the obstructive element is directly bonded to a back side of the semiconductor element opposite an active side, the bonded structure further comprising a through semiconductor via (TSV) extending from a contact pad at or near the active side of the semiconductor element to the contact pad of the obstructive element, the TSV providing electrical communication between the semiconductor element and the detection circuit.

46. A method of forming a bonded structure, the method comprising:
directly bonding a semiconductor element to an obstructive element without an adhesive, the semiconductor element comprising active circuitry, and the obstructive element comprising at least one patterned optically obstructive layer disposed over the active circuitry and that inhibits optical reading of the active circuitry.

47.-70. (canceled)
